(19) United States
(12) Patent Application Publication
(10) Pub. No.: US 2024/0215383 A1
(43) Pub. Date: Jun. 27, 2024

(54) DISPLAY PANEL AND ELECTRONIC DEVICE

(71) Applicant: WUHAN CHINA STAR OPTOELECTRONICS SEMICONDUCTOR DISPLAY TECHNOLOGY CO., LTD., Wuhan (CN)

(72) Inventors: Hanchen LIU, Wuhan (CN); Zhibo DENG, Wuhan (CN)

(73) Assignee: WUHAN CHINA STAR OPTOELECTRONICS SEMICONDUCTOR DISPLAY TECHNOLOGY CO., LTD., Wuhan (CN)

(21) Appl. No.: 18/458,110

(22) Filed: Aug. 29, 2023

(30) Foreign Application Priority Data
Dec. 26, 2022 (CN) 202211680170.X

(51) Int. Cl. H10K 59/80; G06F 3/041; H10K 59/131; H10K 59/40

(52) U.S. Cl. CPC H10K 59/80521; G06F 3/0412; G06F 3/0416; H10K 59/131; H10K 59/40; G06F 2203/04111

(57) ABSTRACT

A display panel and an electronic device are provided in the present application. The display panel includes a driving substrate and a plurality of light-emitting units disposed on the driving substrate. A first electrode layer is disposed on a side of the driving substrate provided with the light-emitting units. The first electrode includes a cathode pattern, and a plurality of touch control units arranged in an array. The cathode pattern is insulated from the plurality of touch control units.

### CROSS-REFERENCE TO RELATED APPLICATION

This application claims priority to Chinese Patent Application No. 202211680170.X, filed on Dec. 26, 2022, which is hereby incorporated by reference in its entirety.

### TECHNICAL FIELD

The present application relates to the field of display technologies, and more particularly, to a display panel and an electronic device.

### BACKGROUND

With development of display technologies, a touch display device provides a new human-computer interaction interface. Currently, the touch display device generally uses a touch screen externally hung on a display panel or integrated in the display panel. However, the touch screen needs to be separately manufactured whether an external hanging or an integrated design is used, which makes it difficult to reduce a thickness of the touch display device. As a result, the touch display device has a thicker thickness.

### SUMMARY

The present application provides a display panel and an electronic device to alleviate the technical problem of thicker thickness of a conventional touch display device.

A display panel is provided according to the present application, the display panel includes: a driving substrate; a plurality of light-emitting units disposed on the driving substrate; wherein a first electrode layer is disposed on a side of the driving substrate provided with the light-emitting units; the first electrode includes a cathode pattern, and a plurality of touch control units arranged in an array; the cathode pattern is insulated from the plurality of touch control units; and the plurality of light-emitting units includes the cathode pattern.

In an embodiment, the cathode pattern includes a plurality of cathode openings, and each of the plurality of touch control units is disposed in a corresponding one of the cathode openings.

In an embodiment, the display panel includes a plurality of touch areas arranged in an array, and the touch control unit is disposed in a corresponding one of the plurality of touch control units; wherein the touch control unit includes a main electrode, and at least one branch electrode electrically connected to the main electrode; the main electrode includes a first main electrode extending in a first direction and a second main electrode extending in a second direction; and wherein the first main electrode and the second main electrode are intersected to divide the touch area into four quadrants, the branch electrodes are provided in each of the quadrant regions, and a gap is provided between any two adjacent branch electrodes.

In an embodiment, in each of the quadrant regions, the branch electrode is connected to the first main electrode and includes at least one sub-electrode, and the sub-electrode includes a first vertical electrode portion and a first horizontal electrode portion connected in series, wherein an included angle is provided between the first vertical electrode portion and the first horizontal electrode portion, and an end of the first vertical electrode portion away from the first horizontal electrode portion is electrically connected to the first main electrode. In a case that a number of the sub-electrodes included in one branch electrode is k, the sub-electrodes are sequentially connected in the second direction, and k is satisfied with: k≥2, wherein k is positive integer. In the case that the number of the sub-electrodes included in one branch electrode is k, the first vertical electrode portion of an e-th sub-electrode and the first vertical electrode portion of an (e+1)-th sub-electrode are connected in series, and e and k are satisfied with: e≥1, k≥e+1, wherein e is positive integer.

In an embodiment, in the first vertical electrode portion extends in the second direction and the first horizontal electrode portion extends in the first direction.

In an embodiment, in each of the quadrant regions, a number of the branch electrodes connected to the first main electrode is f, the first main electrode is equally divided by the branch electrodes into first segments of f, and a length of each of the first segments is a, wherein the first main electrode has equal points of f, and each of the branch electrodes is electrically connected to the first main electrode at a corresponding one of the equal points. A length of the first horizontal electrode portion is less than a, and a and f are respectively satisfied with: f 1, a>0, wherein f is positive integer; in each of the quadrant regions, a number of the branch electrodes connected to the second main electrode is f, the second main electrode is equally divided by the branch electrodes into second segments of f. A length of each of the second segments is b, and wherein a length of the first vertical electrode portion of the sub-electrode connected to the first main electrode is less than b, and b is satisfied with: b>0.

In an embodiment, in each of the quadrant regions, in a case that a number of the branch electrodes connected to the first main electrode is f, a number of the sub-electrodes of an n-th branch electrode is less than a number of the sub-electrodes of an m-th branch electrode. The n-th and the m-th are defined in a direction from an end of the first main electrode close to the second main electrode to another end of the first main electrode away from the second main electrode; and f, m and n are satisfied with: f≥m>n≥1; wherein f, m, and n are all positive integers. The number of the sub-electrodes of the n-th branch electrode is p less than the number of the sub-electrodes of the m-th branch electrode; and m, n and p are satisfied with m=n+1, p≥1; wherein p is positive integer.

In an embodiment, in each of the quadrant regions, f of in a case that a number of the branch electrodes connected to the first main electrode is f, a number of the sub-electrodes of an n-th branch electrode is less than a number of the sub-electrodes of an m-th branch electrode, a number of the sub-electrodes of an s-th branch electrode is less than the number of the sub-electrodes of the m-th branch electrode; wherein the n-th, m-th, and s-th are defined in a direction from an end of the first main electrode close to the second main electrode to another end of the first main electrode away from the second main electrode; and f, s, m, and n are satisfied with: f≥s>m>n≥1; wherein f, s, m, and n are positive integers. The number of the sub-electrodes of the n-th branch electrode is p less than a number of the sub-electrodes of an (n+1)-th branch electrode, and the number of the sub-electrodes of the s-th branch electrode is p less than a number of the sub-electrodes of an (s−1)-th branch electrode; wherein m, n, s and p are satisfied with: m≥n+1, m≤s−1, p≥1; wherein p is positive integer.

In an embodiment, a plurality of sub-pixels arranged in an array are provided on the driving substrate, each of the plurality of sub-pixel corresponds to one of the light-emitting units, a pixel gap is provided between adjacent sub-pixels, the touch control unit corresponds to the pixel gap, and the main electrode and the branch electrode surround the sub-pixel; wherein the sub-pixel includes a green sub-pixel, and the green sub-pixel has an arrangement direction same as an extension direction of the main electrode portion and the branch electrode portion around the green sub-pixel.

In an embodiment, in any adjacent quadrant regions, the branch electrodes in one of the quadrant regions and the branch electrodes in another of the quadrant regions are axially symmetrical.

In an embodiment, in each of the quadrant regions, the branch electrodes connected on the first main electrode and the branch electrodes connected on the second main electrode are axially symmetrical.

In an embodiment, the driving substrate includes a driving circuit, at least one first signal line, and a plurality of second signal lines, the least one first signal line and the plurality of second signal lines are respectively disposed in a same layer as a part of a metal layer of the driving circuit, the cathode pattern is electrically connected to the at least one first signal line, and the touch control units is electrically connected to a corresponding one of the plurality of second signal lines.

In an embodiment, the driving substrate further includes: a planarization layer disposed on the driving circuit, wherein the planarization layer includes a first opening provided corresponding to the second signal line, and the first opening exposes a portion of the second signal line; and a pixel definition layer disposed on the planarization layer, wherein the pixel definition layer includes a second opening provided corresponding to the first opening, and the first opening and the second opening define an undercut structure; wherein the first electrode layer is disposed on a side of the pixel definition layer away from the planarization layer, the first electrode layer is disconnected at the undercut structure to form the cathode pattern and the touch control unit, and the touch control unit extends into the first opening and the second opening to electrically connect with the second signal line.

In an embodiment, the cathode pattern and the touch control unit has a vertical gap defined between the first opening and the second opening.

In an embodiment, at least one first bridge point is provided in each touch control unit, the touch control unit is electrically connected to the second signal line through the first bridge point, and the first bridge point is disposed at an intersection of the first main electrode and the second main electrode; and at least one second bridge point is provided on the cathode pattern, the cathode pattern is electrically connected to the first signal line through the second bridge point, and the second bridge points is disposed in a unit gap between two adjacent touch control units.

In an embodiment, wherein the second bridge point includes a first sub-bridge point disposed a unit gap defined by adjacent four touch control units, and any adjacent four touch control units shares one first sub-bridge point.

In an embodiment, the second bridge point further includes a second sub-bridge point disposed between two adjacent first sub-bridge points, and the second sub-bridge point has an equal distance to the two adjacent first sub-bridge points.

In an embodiment, wherein a plurality of third bridge points are further provided on each touch control unit, the plurality of third bridge points are disposed on the first main electrode and the second main electrode, and the first sub-bridge point has an equal distance to the plurality of third bridge points.

An electronic device is further provided in the present application. The electronic device includes the display panel of the above embodiments.

### BRIEF DESCRIPTION OF THE DRAWINGS

In order that the embodiments of the present application or the technical solutions in the existing technologies may be described more clearly, reference is now made to the accompanying drawings to be used in the description of the embodiments or the existing technologies. It should be understood that the accompanying drawings in the description are merely exemplary of the present application, and that other drawings may be made to those skilled in the art without involving any inventive effort.

FIG. 1 is a schematic top view of a display panel according to an embodiment of the present application.

FIG. 2 is a schematic sectional view of a display panel according to an embodiment of the present application.

FIG. 3 is a detailed structural diagram of one touch control unit of FIG. 1.

FIG. 4 is a detailed structural diagram of a first quadrant region of FIG. 3.

FIG. 5 is a schematic diagram of an arrangement of pixels in the first quadrant region of FIG. 4.

FIG. 6 is another schematic top view of a display panel according to an embodiment of the present application.

FIG. 7 is a detailed structural diagram of one touch control unit of FIG. 6.

FIG. 8 is a detailed structural diagram of a first quadrant region of FIG. 7.

FIG. 9 is yet another schematic top view of a display panel according to an embodiment of the present application.

FIG. 10 is yet another schematic top view of a display panel according to an embodiment of the present application.

### DETAILED DESCRIPTION OF THE EMBODIMENTS

The following description of the embodiments is provided with reference to drawings to illustrate embodiments that the present application can be implemented. The terms mentioned in the present application, for example, “on”, “under”, “front”, “rear”, “left”, “right”, “in”, “out”, “side”, and the like, are merely referring to the orientation in the drawings. Therefore, the directional terms are used to explain and understand the present application, instead of limiting the present application. In the drawings, components having similar structures are denoted by the same reference numerals. In the drawings, the thickness of some layers and areas is enlarged for clear understanding and easy description. That is, the size and thickness of the component shown in the drawings are not showed in a fixed ratio, but the present application is not limited thereto.

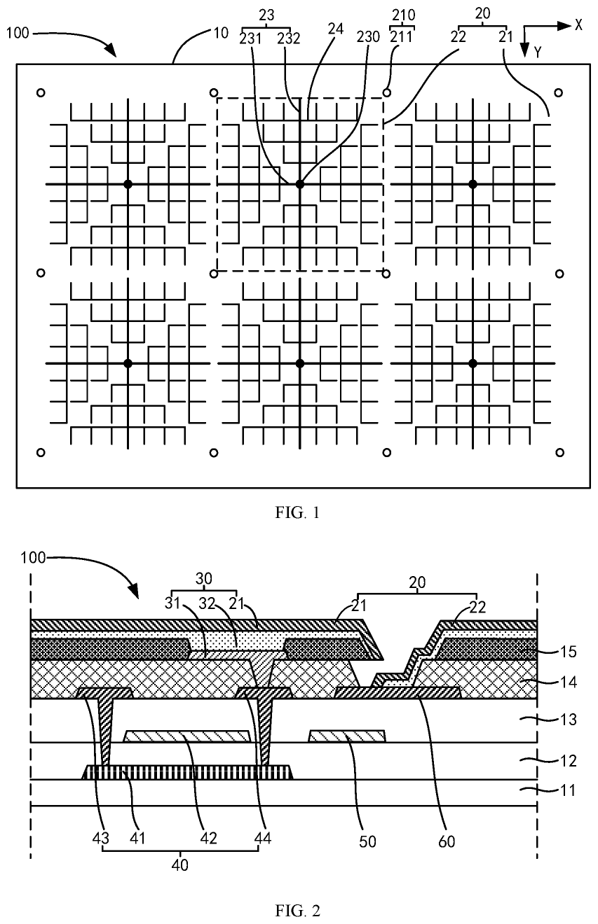

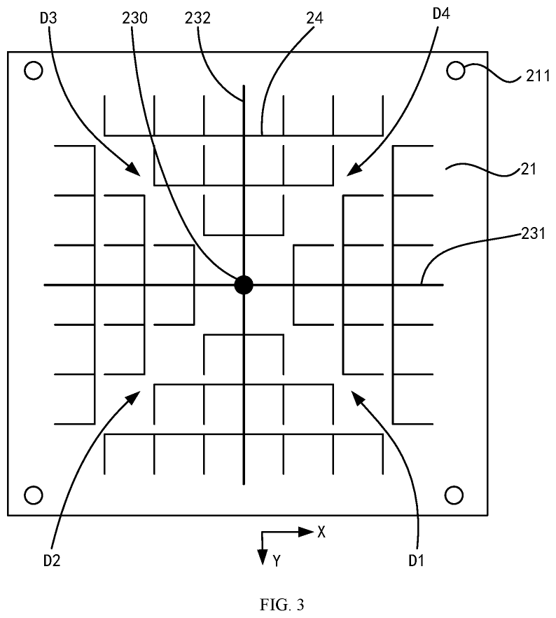

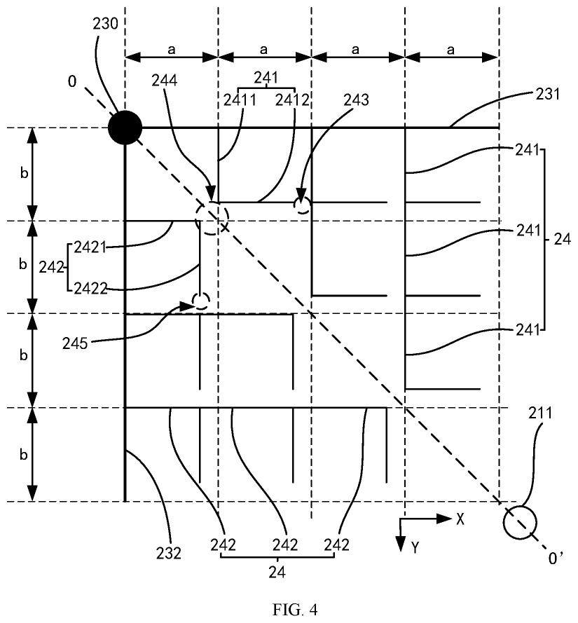

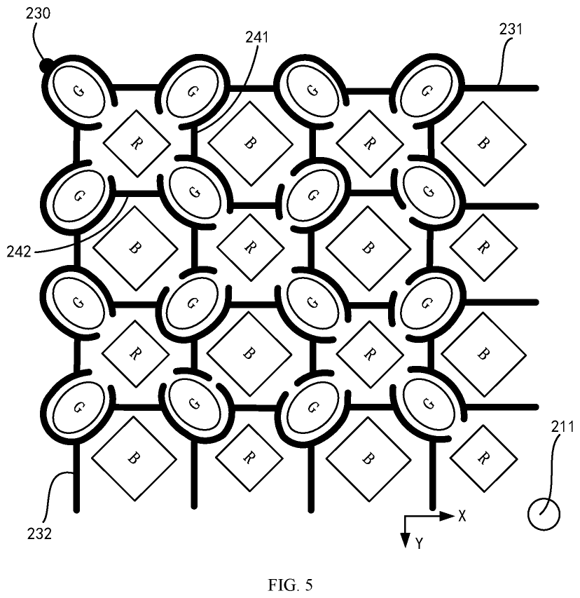

Referring to FIG. 1 to FIG. 5, FIG. 1 is a schematic top view of a display panel according to an embodiment of the present application; FIG. 2 is a schematic sectional view of a display panel according to an embodiment of the present application; FIG. 3 is a schematic detailed structural diagram of one touch control unit in FIG. 1; FIG. 4 is a schematic detailed structural diagram of a first quadrant region in FIG. 3; and FIG. 5 is a schematic diagram of an arrangement of pixels in the first quadrant region of FIG. 4. The display panel 100 includes a driving substrate 10, and a plurality of light-emitting units 30 disposed on the driving substrate 10. A first electrode layer 20 is disposed on a side of the driving substrate 10 provided with the light-emitting units 30. The first electrode layer 20 includes a cathode pattern 21, and a plurality of touch control units 22 arranged in an array. The cathode pattern 21 and the touch control units 22 are insulated from each other. The light-emitting unit 30 includes the cathode pattern 21.

Thus, the cathode pattern 21 and the touch control unit 22 are formed on the first electrode layer 20, this is, the touch control unit 22 is provided on a same layer as the cathode pattern 21. As such, there is no need to separately manufacture a touch control layer, and the thickness of the display panel 100 is reduced, thereby solving a problem of thick thickness of a conventional touch control display device.

In an embodiment, as shown in FIG. 1, the plurality of the touch control units 22 are spaced in a first direction X, and the plurality of the touch control units 22 are spaced in a second direction Y, so that the plurality of the touch control units 22 are arranged in an array on the driving substrate 10. Each of the touch control units 22 has a quadrilateral shape. Sides of two adjacent touch control units 22 in the first direction X are opposite; and sides of two adjacent touch control units 22 in the second direction Y are opposite.

Each touch control unit 22 is a minimum repeatable unit, and each touch control unit 22 includes a main electrode 23 and a branch electrode 24 electrically connected to the main electrode 23. The main electrode 23 includes a first main electrode 231 extending in the first direction X and a second main electrode 232 extending in the second direction Y. The first main electrode 231 and the second main electrode 232 are intersected.

It should be noted that FIG. 1 illustrates six of the touch control units 22, but the present application is not limited thereto, and the display panel 100 of the present application may include more or fewer of the touch control units 22. The first direction X is a horizontal direction, the second direction Y is a vertical direction, and the included angle between the first direction X and the second direction Y is 90 degrees. However, the present application is not limited thereto, and the included angle between the first direction X and the second direction Y in the present application may also be another included angle greater than 0 degrees.

It should be understood that the touch control unit 22 and the cathode pattern 21 are provided in the same layer and are insulated from each other. The touch control unit 22 and the cathode pattern 21 function different, for example, the touch control unit 22 is used to implement the touch control function of the display panel 100, and the cathode pattern 21 is used to implement the display function of the display panel 100. Thus, the touch control unit 22 and the cathode pattern 21 need to connect different signal lines. To this end, the touch control unit 22 and the cathode pattern 21 are provided with bridge points for conducting the signal lines, for example, at least one first bridge point 230 is provided on each touch control unit 22, and at least one second bridge point 210 is provided on the cathode pattern 21.

The first bridge point 230 is positioned at a position where the first main electrode 231 and the second main electrode 232 are intersected, and the second bridge point 210 is located in a unit gap between two adjacent touch control units 22. Alternatively, the second bridge point 210 includes a first sub-bridge point 211, and the first sub-bridge point 211 is located in a unit gap defined by four adjacent touch control units 22, this is, any four adjacent touch control units 22 is provided with one first sub-bridge point 211. In this way, by providing a plurality of the first sub-bridge points 211, and the plurality of the first sub-bridge points 211 are uniformly distributed in the display panel 100, the voltage drop of the cathode pattern 21 can be reduced, and the uniform display of the display panel 100 can be improved.

In an embodiment, referring to FIG. 2, in order to realize the connection of the touch control unit 22 and the cathode pattern 21 to corresponding signal lines, the driving substrate 10 of the display panel 100 is provided with a driving circuit 40, at least one first signal line 50, and a plurality of second signal lines 60. The at least one first signal line 50 and the plurality of second signal lines 60 are respectively provided in a same layer as a part of the metal layer of the driving circuit 40. The cathode pattern 21 is electrically connected to the at least one first signal line 50, and each touch control unit 22 is electrically connected to a corresponding one of the second signal lines 60. The touch control unit 22 is electrically connected to the corresponding second signal line 60 through the first bridge point 230, and the cathode pattern 21 is electrically connected to the first signal line 50 through the second bridge point 210.

Specifically, the display panel 100 includes the driving substrate 10, and the light-emitting unit 30 provided on the driving substrate 10. The driving substrate 10 includes a substrate base 11, the driving circuit 40, the first signal line 50, and the second signal line 60, wherein the driving circuit 40, the first signal line 50, and the second signal line 60 are disposed on the substrate base 11. The driving circuit 40 is used to drive the light-emitting unit 30 to emit lights.

In an embodiment, the substrate base 11 may be a rigid substrate or a flexible substrate. In a case that the substrate base 11 is a rigid substrate, the rigid substrate may be such as a glass substrate. In a case that the substrate base 11 is a flexible substrate, the flexible substrate may be such as a polyimide (PI) film or an ultra-thin glass film. In a case that the substrate base 11 is a flexible substrate, the display panel 100 can perform functions such as bending, curving, and folding.

With continued reference to FIG. 2, the driving circuit 40 is provided on the substrate base 11, and optionally, a buffer layer (not shown) may be provided between the driving circuit 40 and the substrate base 11, the buffer layer may include a silicon oxide film, a silicon nitride film, or a multilayer including a silicon oxide film and a silicon nitride film. The buffer layer may prevent undesirable impurities or contaminants (e.g., moisture, oxygen, etc.) from diffusing from the substrate base 11 into devices that may be damaged by these impurities or contaminants, while the buffer layer also provides a flat top surface.

The driving circuit 40 includes an active layer 41, a gate electrode 42, a source electrode 43, and a drain electrode 44. Meanwhile, the display panel 100 further includes a plurality of insulating layers in order to insulate the metal layers in the driving circuit 40 from each other. Specifically, the active layer 41 is provided on the substrate base 11, and the material of the active layer 41 includes a semiconductor material such as a metal oxide. A gate insulating layer 12 covers the active layer 41 and the substrate base 11.

The gate electrode 42 is provided on the gate insulating layer 12 and corresponds to a channel of the active layer 41. An interlayer insulating layer 13 covers on the gate electrode 42 and the gate insulating layer 12. The source electrode 43 and the drain electrode 44 are provided on the interlayer insulating layer 13, the source electrode 43 is electrically connected to the source region of the active layer 41 through a via hole of the interlayer insulating layer 13, and the drain electrode 44 is electrically connected to the drain region of the active layer 41 through another via hole of the interlayer insulating layer 13. The source region and the drain region are located on opposite sides of the channels of the active layer 41, respectively. A planarization layer 14 covers on the source electrode 43, the drain electrode 44, and the interlayer insulating layer 13.

In an embodiment, the gate electrode 42, the source electrode 43, and the drain electrode 44 are made of a metal material such as copper or molybdenum. The gate insulating layer 12, the interlayer insulating layer 13, and the planarization layer 14 are each made of an inorganic material such as silicon oxide or silicon nitride. It should be noted that the structure of the driving circuit 40 described in the present application is not limited thereto, and the driving circuit 40 described in the present application may also have a circuit structure such as a bottom gate, a double gate, or a double-layer source/drain electrode.

Although the first signal line 50 is disposed in the same layer as the gate electrode 42, and the second signal line 60 is disposed in the same layer as the source electrode 43 or the drain electrode 44, the present application is not limited thereto. The first signal line 50 and the second signal line 60 may be respectively disposed in the same layer as another metal layers of the driving circuit 40. It should be noted that in the present application, the expression “disposed in the same layer” refers to a preparation process that a film layer formed of the same material is patterned to obtain at least two different structures, and the at least two different structures are disposed in the same layer. For example, the first signal line 50 and the gate electrode 42 of the present embodiment are obtained by patterning the same conductive film layer, the first signal line 50 and the gate electrode 42 are disposed in the same layer.

The light-emitting unit 30 is disposed on the driving circuit 40, and includes the cathode pattern 21, a second electrode 31, and a light-emitting functional layer 32 disposed between the cathode pattern 21 and the second electrode 31. The second electrode 31 is an anode, and the second electrode 31 is provided on the planarization layer 14 and is electrically connected to the drain electrode 44 through a via hole on the planarization layer 14. At the same time, the planarization layer 14 is further provided with a first opening corresponding to the second signal line 60, and the first opening exposes a part of the second signal line 60.

A pixel definition layer 15 covers the second electrode 31 and the planarization layer 14, the pixel definition layer 15 is provided with a second opening at a position corresponding to the second electrode 31, the second opening exposes a part of the second electrode 31. At the same time, the pixel definition layer 15 is provided with third opening at a position corresponding to the second signal line 60, and the third opening is opposite to a first opening in the planarization layer 14. Moreover, the third opening and the first opening in the planarization layer 14 together define an undercut structure between the pixel definition layer 15 and the planarization layer 14.

The light-emitting functional layer 32 covers the pixel definition layer 15 and the second electrode 31 and is disconnected at the undercut structure. The first electrode layer 20 covers the light-emitting functional layer 32 and is disconnected at the undercut structure, to form the cathode pattern 21 and the touch control unit 22. That is, the cathode pattern 21 is provided with a cathode opening, and the touch control unit 22 is located in the cathode opening, to realize physical separation of the touch control unit 22 and the cathode pattern 21, thereby realizing insulation between the touch control unit 22 and the cathode pattern 21.

In this way, the first electrode layer 20 is provided as a whole in a top view after patterning. The first electrode layer 20 includes a first region for the touch control unit 22 and a second region for the cathode pattern 21, and the first region has the patterns of electrodes of the touch control unit 22. The touch control unit 22 is physically separated from the cathode pattern 21 so as to be insulated from each other. The orthographic projection of the touch control unit 22 on the substrate base 11 and the orthographic projection of the cathode pattern 21 on the substrate base 11 are contacted or partially overlapped, this is, there is no gap between the orthographic projection of the touch control unit 22 on the substrate base 11 and the orthographic projection of the cathode pattern 21 on the substrate base 11. The present application is not limited thereto, and in another embodiment, the orthographic projection of the touch control unit 22 on the substrate base 11 and the orthographic projection of the cathode pattern 21 on the substrate base 11 may define a gap.

Further, the touch control unit 22 is physically separated from the cathode pattern 21 by the undercut structure, while realizing the electrical connection between the touch control unit 22 and the second signal line 60. Specifically, the touch control unit 22 extends into the third opening in the pixel definition layer 15 and into the first opening in the planarization layer 14, and the touch control unit 22 is electrically connected to the second signal line 60. There is a gap between the cathode pattern 21 and a part of the touch control unit 22 positioned in the third opening and the first opening. The electrical connection between the touch control unit 22 and the second signal line 60 is not limited to the above, and the touch control unit 22 may be electrically connected with the second signal line 60 by via holes.

Similarly, the cathode pattern 21 may be electrically connected to the first signal line 50 by via holes, The first signal line 50 electrically connected to the cathode pattern 21 may be provided in the display panel 100 to reduce the width of the frame of the display panel 100. Compared with that the cathode pattern is provided around the display panel, a narrow frame is obtained by providing the cathode pattern 21 in the display panel 100. It is also advantageous to reduce the voltage drop of the cathode pattern 21, thereby improving the uniform display of the display panel 100.

In addition, the display panel 100 may further include a functional layer such as an encapsulation layer, an anti-reflection layer, and a protective layer, provided on the light-emitting unit 30, which is not be described in detail herein.

The structure of the touch control unit 22 is described in detail by taking one touch control unit 22 as an example.

Referring in conjunction with FIGS. 3 and 4, each touch control unit 22 includes a main electrode 23 and a branch electrode 24 electrically connected to the main electrode 23. The main electrode 23 includes a first main electrode 231 extending in a first direction X and a second main electrode 232 extending in a second direction Y. The display panel 100 includes a plurality of touch areas arranged in an array, and the touch unit 22 is located in the touch area. The first main electrode 231 and the second main electrode 232 are intersected to divide the touch area into four quadrant regions, this is, a first quadrant region D1, a second quadrant region D2, a third quadrant region D3, and a fourth quadrant region D4, as shown in FIG. 3. Each of the quadrant regions includes a plurality of the branch electrodes 24, a gap is defined between any two adjacent branch electrodes 24.

Further, as shown in FIG. 4, in each quadrant region, at least one branch electrode 24 is connected to the first main electrode 231, and each of the at least one branch electrode 24 includes at least one first sub-electrode 241. Each first sub-electrode 241 includes a first vertical electrode portion 2411 and a first horizontal electrode portion 2412 connected in series, the first vertical electrode portion 2411 and the first horizontal electrode portion 2412 are electrically connected, and an included angle is defined between the first vertical electrode portion 2411 and the first horizontal electrode portion 2412. Optionally, the first vertical electrode portion 2411 extends in the second direction Y, and the first horizontal electrode portion 2412 extends in the first direction X. An end of the first vertical electrode portion 2411 away from the first horizontal electrode portion 2412 is electrically connected to the first main electrode 231.

Specifically, in the embodiment of the present application, the structure of the touch control unit 22 is described in detail by taking the first quadrant region D1 as an example, and with continued reference to FIG. 4, a plurality of the branch electrodes 24 are connected to the first main electrode 231. In a case that the number of sub-electrodes 241 included in one branch electrode 24 connected to the first main electrode 231 is k, the sub-electrodes 241 are sequentially arranged along the second direction Y, wherein k is positive integer and is satisfied with k≥2. That is, in a case that one branch electrode 24 connected to the first main electrode 231 includes a plurality of the sub-electrodes 241, the plurality of sub-electrodes 241 are sequentially arranged in the second direction Y, and two adjacent ones of the plurality of sub-electrodes 241 are electrically connected.

In an embodiment, in a case that the number of sub-electrodes 241 included in one branch electrode 24 is provided as k, the first vertical electrode portion 2411 of the e-th sub-electrode 241 and the first vertical electrode portion 2411 of the (e+1)-th sub-electrode 241 are connected in series, wherein e is positive integer, and e and k are satisfied with e≥1, k≥e+1. Specifically, FIG. 4 illustrates that the first main electrode 231 is electrically connected to three branch electrodes 24, but the present application is not limited thereto. The first main electrode 231 of the present application may be electrically connected to more or fewer of the branch electrodes 24. A third branch electrode 24 of the three branch electrodes 24 includes three sub-electrodes 241, wherein the three sub-electrodes 241 are sequentially arranged in the second direction Y. An end of the first vertical electrode portion 2411 of the first one of the threes sub-electrodes 241 is electrically connected to the first main electrode 231, the other end of the first vertical electrode portion 2411 of the first one of the threes sub-electrodes 241 is electrically connected to an end of the first vertical electrode portion 2411 of the second one of the three sub-electrodes 241. The other end of the first vertical electrode portion 2411 of the second one of the three sub-electrodes 241 is electrically connected to the first vertical electrode portion 2411 of the third one of the three sub-electrodes 241.

Further, in each quadrant region, the number of the branch electrodes 24 connected to the first main electrode 231 is f, as such the number of segments of the first main electrode 231 divided by the branch electrodes 24 is f+1, and the length of each segment of the first main electrode 231 is a. The first main electrode 231 has equal points of f, each branch electrode 24 is electrically connected to the first main electrode 231 at a corresponding one of the equal points. The length of the first horizontal electrode portion 2412 is less than a, and f and a are satisfied with f≥1, a>0, wherein f is positive integer.

Specifically, with reference to FIG. 4, for example, the first main electrode 231 is electrically connected to three branch electrodes 24. The first main electrode 231 is equally divided into four segments, and each segment has a length of a. That is, the first main electrode 231 is equalized, and the first main electrode 231 has equal points. The first vertical electrode portion 2411 of the first sub-electrode 241 of each branch electrode 24 is electrically connected to the first main electrode 231 at the corresponding equal point, wherein the first sub-electrode 241 is the one close to the first main electrode 231 in the second direction Y.

In the first direction X, the length of the first horizontal electrode portion 2412 of each of the sub-electrodes 241 is less than a, so that there is a first gap 243 between any two adjacent branch electrodes 24. In an embodiment, the lengths of the first horizontal electrode portions 2412 of each the sub-electrodes 241 are the same. FIG. 4 illustrates a first gap 243 between the first one of the branch electrodes 24 electrically connected to the first main electrode 231 and the second one of the branch electrodes 24 electrically connected to the first main electrode 231, and the first gap 243 connects the cathode pattern 21 in the first sub-electrode 241 of the first one of the branch electrodes 24 connected to the first main electrode 231 with the cathode pattern 21 outside the first one of the sub-electrodes 241 connected to the first main electrode 231, to define a continuous cathode pattern 21.

Further optionally, in each quadrant region, the number of segments of the second main electrode 232 divided by the branch electrodes 24 is f+1, the length of each segment of the second main electrode 232 is b, and the length of the first vertical electrode portion 2411 of the first one of the sub-electrodes 241 connected to the first main electrode 231 is less than b, wherein b is satisfied with b>0.

Specifically, with continued reference to FIG. 4, in each quadrant region, the second main electrode 232 is electrically connected to at least one branch electrode 24, each branch electrode 24 includes at least one second sub-electrode 242, each of the at least one of second sub-electrodes 242 includes a second horizontal electrode portion 2421 extending in a first direction X and a second vertical electrode portion 2422 extending in a second direction Y, one end of the second horizontal electrode portion 2421 away from the first second vertical electrode portion 2422 being electrically connected to the second main electrode 232.

Similarly, the present application takes the second main electrode 232 electrically connected to the branch electrodes 24 with the number of f as an example. However, the present application is not limited thereto, and the number of the branch electrodes 24 electrically connected to the second main electrode 232 may be different from the number of the branch electrodes 24 electrically connected to the first main electrode 231. As shown in FIG. 4, the second main electrode 232 is electrically connected to three branch electrodes 24, and the second main electrode 232 is equally divided into four segments. Each segment has a length of b, that is, the second main electrode 232 is equally divided into four segments to have has three equal points.

The length of the first vertical electrode portion 2411 of the sub-electrode 241 connected to the first main electrode 231 is less than b, so that there is a second gap 244 between the branch electrode 24 connected to the first main electrode 231 and the branch electrode 24 connected to the second main electrode 232, so that the cathode pattern 21 is continuous in conduction. As illustrated in FIG. 4, The second gap 244 is defined between the first one of the branch electrodes 24 connected to the first main electrode 231 and the first one of the branch electrodes 24 connected to the second main electrode 232.

In an embodiment, among the branch electrodes 24 electrically connected to the first main electrode 231, the length of the first vertical electrode portion 2411 of the sub-electrode 241 close to the first main electrode 231 is less than b. That is, the length of the first vertical electrode portion 2411 of the sub-electrode 241 directly connected to the first main electrode 231 is less than b. The length of other first vertical electrode portion 2411 of the sub-electrode 241 not directly connected to the first main electrode 231 may be equal to b.

It should be understood that in order to define a third gap 245 between adjacent two of the branch electrodes 24 electrically connected to the second main electrode 232, the length of the second vertical electrode portion 2422 of each branch electrode 24 is less than b. In order to increase the second gap 244 between the branch electrode 24 on the first main electrode 231 and the branch electrode 24 on the second main electrode 232, the length of the second horizontal electrode portion 2421 of the sub-electrode 242 directly connected to the second main electrode 232 is less than a. The length of the second horizontal electrode portion 2421 on the other sub-electrode 242 not directly connected to the second main electrode 232 may be equal to a.

Further, among the plurality of the branch electrodes 24 electrically connected to the second main electrode 232, the second horizontal electrode portion 2421 of the first one of the sub-electrodes 242 of each branch electrode 24 is electrically connected to the second main electrode 232 at the equal point, wherein the first one of the sub-electrode 242 is close to the second main electrode 232 in the first direction X.

The arrangement of the branch electrodes 24 in each quadrant region is explained in detail below. With continued reference to FIG. 4, in each quadrant region, the number of the branch electrodes 24 connected to the first main electrode 231 is f. The number of the sub-electrodes 241 of the n-th branch electrode 24 is less than the number of the sub-electrodes 241 of the m-th branch electrode 24, wherein n-th and m-th are defined in a direction from an end of the first main electrode 231 close to the second main electrode 232 to another end of the first main electrode 231 away from the second main electrode 232, and f, m and n are satisfied with f≥m>n≥1, wherein f, m, and n are all positive integers.

Specifically, as shown in FIG. 4, three branch electrodes 24 are connected to the first main electrode 231, wherein the number of the sub-electrodes 241 of the first one of the branch electrodes 24 is one, the number of the sub-electrodes 241 of the second one of the branch electrodes 24 is two, and the number of the sub-electrodes 241 of the third one of the branch electrodes 24 is three, in a direction from an end of the first main electrode 231 close to the second main electrode 232 to another end of the first main electrode 231 away from the second main electrode 232. As such, the number of the sub-electrodes 241 of the first one of the branch electrodes 24 is less than the number of the sub-electrodes 241 of another two of the branch electrodes 24. That is, in the direction from an end of the first main electrode 231 close to the second main electrode 232 to another end of the first main electrode 231 away from the second main electrode 232, among the plurality of branch electrodes 24 connected to the first main electrode 231, the number of the sub-electrodes 241 of the branch electrodes 24 close to the second main electrode 232 is less than the number of the sub-electrodes 241 of the branch electrodes 24 away from the second main electrode 232.

Further, the number of the sub-electrodes 241 of the n-th branch electrode 24 is p less than the number of the sub-electrodes 241 of the m-th branch electrode 24, where p is positive integer, and m, n and p are satisfied with m=n+1, p≥1. Thus, in the direction from an end of the first main electrode 231 close to the second main electrode 232 to another end of the first main electrode 231 away from the second main electrode 232, among the plurality of branch electrodes 24 connected to the first main electrode 231, the number of the sub-electrodes 241 of the branch electrode 24 gradually increases as the distance between the branch electrode 24 and the second main electrode 232 gradually increases. For example, as shown in FIG. 4, among the plurality of branch electrodes 24 electrically connected to the first main electrode 231, the number of the sub-electrodes 241 of the second one of the branch electrodes 24 is one more than the number of the sub-electrodes 241 of the first one of the branch electrodes 24, and the number of the sub-electrodes 241 of the third one of the branch electrodes 24 is one more than the number of the sub-electrodes 241 of the second one of the branch electrodes 24.

In an embodiment, in each quadrant region, the branch electrodes 24 on the first main electrode 231 and the branch electrodes 24 on the second main electrode 232 are axially symmetrical, such that the branch electrodes 24 on the second main electrode 232 are arranged same as the branch electrodes 24 on the first main electrode 231. As shown in FIG. 4, the branch electrodes 24 on the first main electrode 231 are axially symmetrical with the branch electrodes 24 on the second main electrode 232 with respect to the bisecting line 00′ of the first quadrant region D1, so that the branch electrodes 24 on the second main electrode 232 have the same arrangement as the branch electrodes 24 on the first main electrode 231, and the arrangement of the branch electrodes 24 on the second main electrode 232 is not described herein. The bisecting line of the first quadrant region D1 refers to a virtual line bisecting the first quadrant region D1.

Thus, in the first quadrant region D1, the branch electrodes 24 on the first main electrode 231 and the branch electrodes 24 on the second main electrode 232 are arranged regularly so as to minimize the average distance from each point on the touch control unit 22 in the first quadrant region D1 to the first bridge point 230, and the average distance from each point on the cathode pattern 21 in the first quadrant region D1 to the second bridge point 210, thereby optimizing the wiring design in the first quadrant region D1 and avoiding the occurrence of the winding of the wiring.

The specific arrangement of the main electrode 23 and the branch electrode 24 of the touch control unit 22 is further described in connection with the specific pixel arrangement.

Referring to FIG. 4 and FIG. 5, one quadrant region is taken as an example to show the pixel arrangement. A plurality of sub-pixels arranged are provided in an array on the driving substrate, each of the sub-pixels corresponds to one of the light-emitting units 30, and a pixel gap is defined between adjacent sub-pixels. The plurality of sub-pixels may include a plurality of red sub-pixels R, a plurality of green sub-pixels G, and a plurality of blue sub-pixels B, wherein four of the green sub-pixels G are defined a void, and a plurality of the void are provided. The red sub-pixel R is in one of the voids, and the blue sub-pixel B is in another one of the voids. The touch control unit 22 is disposed in the pixel gap, and the first main electrode 231, the second main electrode 232, and the branch electrodes 24 are around the sub-pixel. The portion of the main electrode and the portion of the branch electrode around the green sub-pixels G extends in a same direction with the arrangement of the green sub-pixels G. The first main electrode 231 extends along the first direction X as a whole, and the second main electrode 232 extends along the second direction Y as a whole.

The first gap 243 is defined between adjacent branch electrodes 24 on the first main electrode 231, and each branch electrode 24 on the first main electrode 231 includes at least one sub-electrode 241. As the distance between the branch electrode 24 on the first main electrode 231 and the second main electrode 232 increases, the number of sub-electrodes 241 of the branch electrode 24 on the first main electrode 231 increases. The third gap 245 between two adjacent branch electrodes 24 on the second main electrode 232, each branch electrode 24 on the second main electrode 232 includes at least one sub-electrode 242. As the distance between the branch electrode 24 on the second main electrode 232 and the first main electrode 231 increases, the number of sub-electrodes 241 of the branch electrode 24 on the second main electrode 232 increases. Meanwhile, the second gap 244 is defined between the branch electrode 24 on the first main electrode 231 and the corresponding branch electrode 24 on the second main electrode 232.

It should be noted that in each quadrant region, the number of the branch electrodes 24 and the number of the sub-electrodes 241 of the branch electrodes 24 can be adjusted according to the sub-pixels. That is, the arrangement of the branch electrodes 24 in each quadrant region can be adjusted with the arrangement of the sub-pixels, but the principle of the arrangement of the branch electrodes 24 is the same.

In an embodiment, in any adjacent quadrant regions, the branch electrodes 24 on the first main electrode 231 in one quadrant region are axially symmetrical with the branch electrodes 24 on the first main electrode 231 in the other quadrant region relative to the first main electrode 231; similarly, the branch electrodes 24 on the second main electrode 232 in one quadrant region are axially symmetrical with the branch electrodes 24 on the second main electrode 232 in the other quadrant region relative to the second main electrode 232. As such, the principle of the arrangement of the branch electrodes 24 in each quadrant region is the same. For example, the branch electrodes 24 in the second quadrant region D2, the branch electrodes 24 in the third quadrant region D3, and the branch electrodes 24 in the fourth quadrant region D4 share the same principle of the arrangement of the branch electrodes 24 in the first quadrant region D1. Thus, the average distance from each point on the touch control unit 22 in each quadrant region to the first bridge point 230 is minimized, and the average distance from each point on the cathode pattern 21 to the corresponding second bridge point 210 is minimized. Further, the wiring design in the display panel 100 is optimized to avoid the occurrence of the winding.

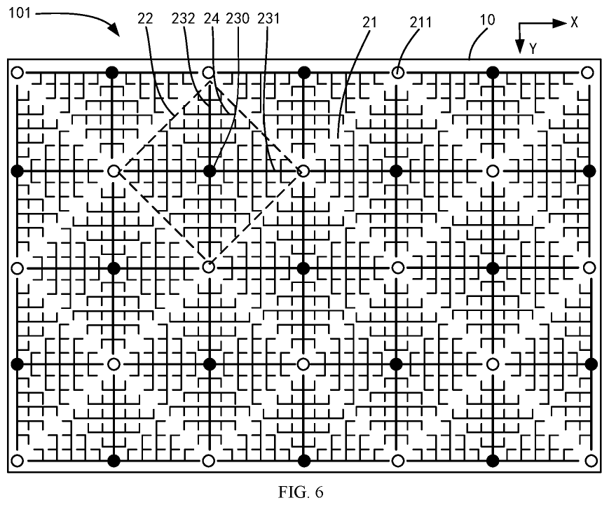

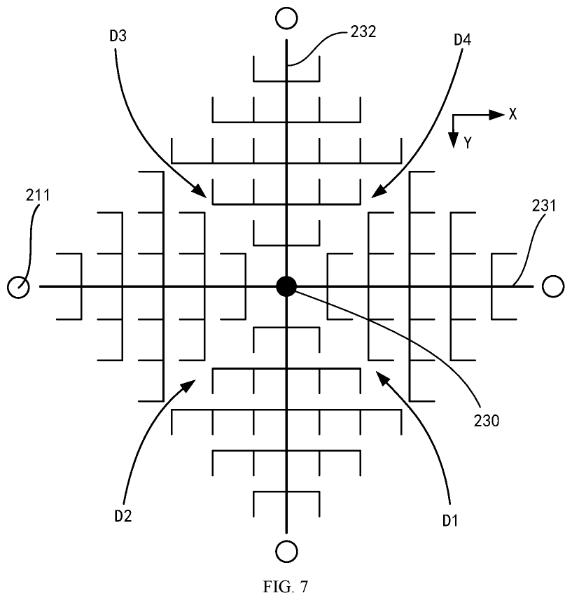

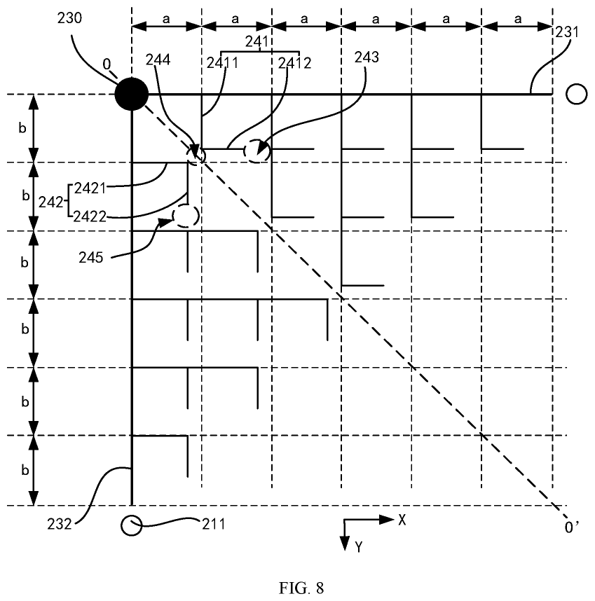

In an embodiment, reference is made to FIGS. 1 to 8. FIG. 6 is another schematic top view of a display panel according to an embodiment of the present application; FIG. 7 is a detailed structural diagram of one touch control unit of FIG. 6; and FIG. 8 is a detailed structural diagram of a first quadrant region of FIG. 7. According to the display panel 101 of the present embodiment, the touch control unit 22 is arranged in an array on the driving substrate 10, and the touch control unit 22 is quadrilateral. The principle of the arrangement of the branch electrodes 24 in each quadrant of the touch control unit 22 is different from that in the above-described embodiment. In the first direction X, the vertices of two adjacent said touch control units 22 are opposite, and in the second direction Y, the vertices of two adjacent touch control units 22 are opposite, as shown in FIG. 6. It should be understood that for display panels of different shapes, the touch control unit 22 is required to adapt the shape of the display panel, thus, the touch control unit 22 in the edge position of the display panel may be an incomplete shape. As shown in FIG. 6, the touch control unit 22 in the edge position of the display panel 101 is an incomplete shape.

Specifically, referring to FIGS. 7 and 8, the touch control unit 22 is divided into four quadrant regions by the first main electrode 231 and the second main electrode 232. The four quadrant regions include a first quadrant region D1, a second quadrant region D2, a third quadrant region D3, and a fourth quadrant region D4, as shown in FIG. 7. In this embodiment, the arrangement of the branch electrodes 24 in the touch control unit 22 is described by taking the first quadrant region D1 as an example.

Referring to FIG. 8, in each quadrant region, the number of the branch electrodes 24 connected to the first main electrode 231 is f, the first main electrode 231 is divided into segments by the branch electrodes 24, and the first main electrode 231 has f equal points. The length of the segment of the first main electrode 231 is a. Each branch electrode 24 is electrically connected to the first main electrode 231 at the equal point. The length of the first horizontal electrode portion 2412 is less than a, and a and f are satisfied with f≥1, a>0, wherein f is positive integer. The number of the branch electrodes 24 connected to the second main electrode 232 is f, and the second main electrode 232 is divided into segments by the branch electrodes 24. The length of the segment of the second main electrode 232 is b, where b>0. The length of the first vertical electrode portion 2411 of the sub electrode 241 connected to the first main electrode 231 is less than b.

Specifically, with reference to FIG. 8, for example, the first main electrode 231 is electrically connected to five branch electrodes 24. The first main electrode 231 is equally divided into six segments by the five branch electrodes 24, and each segment of the first main electrode 231 has a length of a. That is, the first main electrode 231 is divided into six equal segments, so that there are five equal points on the first main electrode 231. The first vertical electrode portion 2411 of the first one of the sub-electrodes 241 of each branch electrode 24 is electrically connected to the first main electrode 231 at the equal point, wherein the first one of the sub-electrode 241 is close to the first main electrode 231 in the second direction Y. The second main electrode 232 is equally divided into six segments, and each segment has a length of b. That is, the second main electrode 232 is divided into six equal segments, so that there are five equal points on the second main electrode 232.

In the first direction X, the length of the first horizontal electrode portion 2412 of each sub-electrode 241 electrically connected to the first main electrode 231 is less than a, so that a first gap 243 is defined between any two adjacent branch electrodes 24, and the cathode pattern 21 is continuous. Optionally, the length of the first horizontal electrode portion 2412 of each sub-electrode 241 is the same. The length of the first vertical electrode portion 2411 of the sub-electrode 241 connected to the first main electrode 231 is less than b, so that a second gap 244 is defined between the branch electrode 24 connected to the first main electrode 231 and the branch electrode 24 connected to the second main electrode 232, and the cathode pattern 21 is continuous in conduction.

In an embodiment, among the branch electrodes 24 electrically connected to the first main electrode 231, the length of the first vertical electrode portion 2411 of the sub-electrode 241 close to the first main electrode 231 is less than b, that is, the length of the first vertical electrode portion 2411 of the sub-electrode 241 directly connected to the first main electrode 231 is less than b. The length of the first electrode portion 2411 of another sub-electrode 241 not directly connected to the first main electrode 231 may be equal to b.

In an embodiment, in each quadrant region, the number of the sub-electrodes 241 of the n-th branch electrode 24 electrically connected to the first main electrode 231 is less than the number of the sub-electrodes 241 of the m-th branch electrode 24, and the number of the sub-electrodes 241 of the s-th branch electrode 24 is less than the number of the sub-electrodes 241 of the m-th branch electrode 24, wherein n-th, m-th, and s-th are defined in a direction from an end of the first main electrode 231 close to the second main electrode 232 to another end of the first main electrode 231 away from the second main electrode 232, and f, s, m, and n are satisfied with f≥s>m>n≥1, wherein f, s, m, and n are positive integers. In a case that f is odd, f and m are satisfied with m=(f+1)/2. In a case that f is even, f and m are satisfied with m=f/2 or m=(f+1)/2.

Specifically, with continued reference to FIG. 8, five branch electrodes 24 are connected to the first main electrode 231. Along a direction from an end of the first main electrode 231 close to the second main electrode 232 to another end of the first main electrode 231 away from the second main electrode 232, the number of the sub-electrodes 241 of the first one of the branch electrodes 24 is one, the number of the sub-electrodes 241 of the second one of the branch electrodes 24 is two, the number of the sub-electrodes 241 of the third one of the branch electrodes 24 is three, the number of the sub-electrodes 241 of the fourth one of the branch electrodes 24 is two, and the number of the sub-electrodes 241 of the fifth one of the branch electrodes 24 is one. Thus, the number of the sub-electrodes 241 of the first one of the branch electrodes 24 is less than the number of the sub-electrodes 241 of the following two of the branch electrodes 24, and the number of the sub-electrodes 241 of the fifth one of the branch electrodes 24 is less than the number of the sub-electrodes 241 of the preceding two of the branch electrodes 24. That is, among the plurality of branch electrodes 24 connected to the first main electrode 231, the number of the sub-electrodes 241 of the branch electrode 24 firstly increases and then decreases along a direction from an end of the first main electrode 231 close to the second main electrode 232 to another end of the first main electrode 231 away from the second main electrode 232.

Further, the number of the sub-electrodes 241 of the n-th branch electrode 24 is p less than the number of the sub-electrodes 241 of the (n+1)-th branch electrode 24, and the number of the sub-electrodes 241 of the s-th branch electrode 24 is p less than the number of the sub-electrodes 241 of the (s−1)-th branch electrode 24, m, n, s and p are satisfied with: m≥n+1, m≤s−1, p≥1, where p is positive integer. Thus, along a direction from an end of the first main electrode 231 close to the second main electrode 232 to another end of the first main electrode 231 away from the second main electrode 232, among the plurality of branch electrodes 24 connected to the first main electrode 231, as the distance between the branch electrode 24 and the second main electrode 232 gradually increases, the number of the sub-electrodes 241 of the branch electrode 24 gradually increases firstly and then gradually decreases. For example, as shown in FIG. 8, among the plurality of branch electrodes 24 electrically connected to the first main electrode 231, the number of the sub-electrodes 241 of the second one of the branch electrodes 24 is one more than the number of the sub-electrodes 241 of the first one of the branch electrodes 24, the number of the sub-electrodes 241 of the third one of the branch electrodes 24 is one more than the number of the sub-electrodes 241 of the second one of the branch electrodes 24, the number of the sub-electrodes 241 of the fourth one of the branch electrodes 24 is one less than the number of the sub-electrodes 241 of the third one of the branch electrodes 24, and the number of the sub-electrodes 241 of the fifth one of the branch electrodes 24 is one less than the number of the sub-electrodes 241 of the fourth one of the branch electrodes 24.

In an embodiment, in each quadrant region, the branch electrodes 24 on the first main electrode 231 and the branch electrodes 24 on the second main electrode 232 are axially symmetrical, such that the branch electrodes 24 on the second main electrode 232 are arranged same as the branch electrodes 24 on the first main electrode 231. As shown in FIG. 8, the branch electrodes 24 on the first main electrode 231 are axially symmetrical with the branch electrodes 24 on the second main electrode 232 with respect to the bisecting line OO′ of the first quadrant region D1, so that the branch electrodes 24 on the second main electrode 232 have the same arrangement as the branch electrodes 24 on the first main electrode 231, and the arrangement of the branch electrodes 24 on the second main electrode 232 is not described herein.

Thus, in the first quadrant region D1, the branch electrodes 24 on the first main electrode 231 and the branch electrodes 24 on the second main electrode 232 are arranged regularly so as to minimize the average distance from each point on the touch control unit 22 in the first quadrant region D1 to the first bridge point 230, and the average distance from each point on the cathode pattern 21 in the first quadrant region D1 to the second bridge point 210, thereby optimizing the wiring design in the first quadrant region D1 and avoiding the occurrence of the winding of the wiring.

In an embodiment, in any adjacent quadrant regions, the branch electrodes 24 in one quadrant region and the branch electrodes 24 in another quadrant region are axially symmetrical, so that the principle of the arrangement of the branch electrodes 24 in each quadrant region is the same, for example, the branch electrodes 24 in the second quadrant region D2, the branch electrodes 24 in the third quadrant region D3, and the branch electrodes 24 in the fourth quadrant region D4 have same as the principle of the arrangement of the branch electrode 24 in the first quadrant region D1, so that the average distance from each point on the touch control unit 22 in each quadrant region to the first bridge point 230 is minimized, and the average distance from each point on the cathode pattern 21 to the corresponding second bridge point 210 is minimized, thereby optimizing the wiring design in the entire display panel 101 to avoid the occurrence of the winding. In addition, according to the principle of the arrangement of the branch electrodes 24 in the touch control unit 22 of the present embodiment, the touch control units 22 can be tightly arranged, the pixels in the display panel 101 can be tightly arranged, and the pixel gap between the pixels are reduced. Thus, an excessive gap between the pixels is avoided, thereby improving the density of the pixels of the display panel 101.

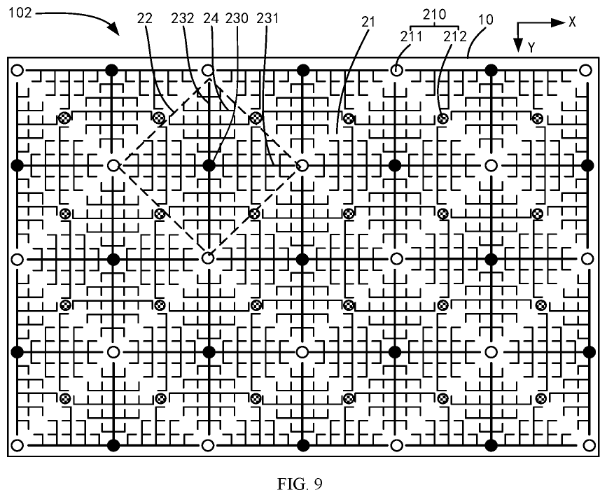

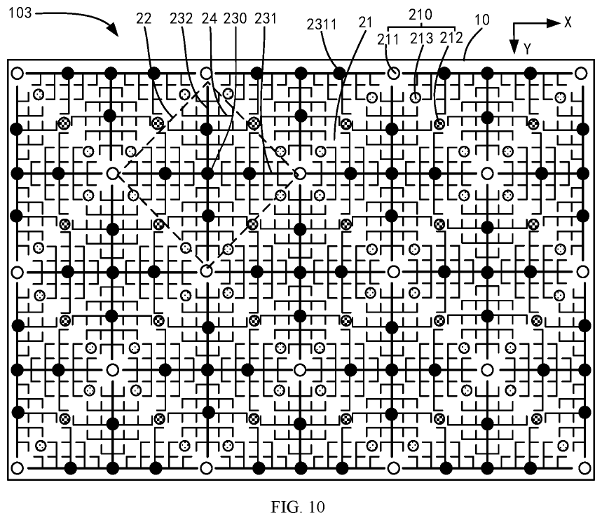

In an embodiment, reference is made to FIGS. 1 to 10, and FIG. 9 is yet another schematic top view of a display panel according to an embodiment of the present application. According to the display panel 102 of the present embodiment, the second bridge point 210 further includes a second sub-bridge point 212 located between two adjacent first sub-bridge points 211, and the distance between the second sub-bridge point 212 and one of the two adjacent first sub-bridge points 211 is equal to the distance between the second sub-bridge point 212 and the other one of the two adjacent first sub-bridge points 211. By providing the second sub-bridge point 212, the conductive channel between the cathode pattern 21 and the first signal line 50 is increased, so that the voltage drop of the cathode pattern 21 can be further reduced, thereby further improving the uniform display of the display panel 102. For other description, references are made to the above-mentioned embodiments, and details are not described herein.

In an embodiment, references are made to FIGS. 1 to 10, FIG. 10 is yet another schematic top view of a display panel according to an embodiment of the present application. According to the display panel 103 of the present embodiment, the second bridge point 210 further includes a third sub-bridge point 213 located between the first sub-bridge point 211 and the second sub-bridge point 212 adjacent to the first sub-bridge point 211. Four adjacent third sub-bridge points 213 surround one first sub-bridge point 211 and are centrally symmetrical relative to the first sub-bridge point 211. By providing the third sub-bridge point 213, the conduction channel between the cathode pattern 21 and the first signal line 50 is further increased, so that the voltage drop of the cathode pattern 21 can be further reduced, thereby further improving the uniform display of the display panel 102.

In addition, a plurality of third bridge points 2311 are provided on each touch control unit 22, and the plurality of third bridge points 2311 are located on the first main electrode 231 and/or the second main electrode 232. The distance from each of the third bridge points 2311 to the corresponding first bridge points 230 are equal. Four adjacent third bridge points 2311 surround one of the first bridge points 230 and are centrally symmetrical relative to the first bridge point 230. By providing the third bridge point 2311, the conduction channel between the touch control unit 22 and the second signal line 60 is increased, thereby providing stability of signal transmission between the touch control unit 22 and the second signal line 60. For other description, references are made to the above-mentioned embodiments, and details are not described herein.

Based on the same inventive concept, an embodiment of the present application further provides an electronic device including a display panel of the above embodiments. The electronic device includes an electronic display device such as a mobile phone, a tablet, a computer, and a television.

The following can be seen from the above embodiments.

The present application provides a display panel and an electronic device. The display panel includes a driving substrate, and a plurality of light-emitting units disposed on the driving substrate. A first electrode layer is disposed on a side of the driving substrate provided with the light-emitting units. The first electrode layer includes a cathode pattern, and a plurality of touch control units arranged in an array. The cathode pattern and the touch control units are insulated from each other. According to the present application, the cathode pattern and the touch control unit are formed on the first electrode layer, so that the touch control unit and the cathode pattern are provided in the same layer. Thus, the touch control layer does not need to be separately manufactured, and the thickness of the display panel is reduced, thereby solving a problem that the thickness of the conventional touch control display device is relatively thick.

In the above-mentioned embodiments, the description of each embodiment has its own emphasis, and parts not described in detail in a certain embodiment may be referred to the related description of other embodiments.

The principles and embodiments of the present application are described herein using specific examples. The foregoing description of the embodiments is merely intended to understand the technical solutions of the present application and the core concepts thereof. It should be understood by those of ordinary skill in the art that modifications may still be made to the technical solutions described in the foregoing embodiments, or equivalents may be made to some of the technical features therein. These modifications or substitutions do not depart the essence of the technical solutions from the scope of the present application.

What is claimed is:

1. A display panel, comprising:
a driving substrate; and
a plurality of light-emitting units disposed on the driving substrate;
wherein a first electrode layer is disposed on a side of the driving substrate provided with the light-emitting units; the first electrode comprises a cathode pattern, and a plurality of touch control units arranged in an array; the cathode pattern is insulated from the plurality of touch control units; and the plurality of light-emitting units includes the cathode pattern.

2. The display panel of claim 1, wherein the cathode pattern comprises a plurality of cathode openings, and each of the plurality of touch control units is disposed in a corresponding one of the cathode openings.

3. The display panel of claim 2, wherein the display panel includes a plurality of touch areas arranged in an array, and the touch control unit is disposed in a corresponding one of the plurality of touch control units; wherein the touch control unit comprises a main electrode, and at least one branch electrode electrically connected to the main electrode; the main electrode comprises a first main electrode extending in a first direction and a second main electrode extending in a second direction; and wherein the first main electrode and the second main electrode are intersected to divide the touch area into four quadrants, the branch electrodes are provided in each of the quadrant regions, and a gap is provided between any two adjacent branch electrodes.

4. The display panel of claim 3, wherein in each of the quadrant regions, the branch electrode is connected to the first main electrode and comprises at least one sub-electrode, and the sub-electrode comprises a first vertical electrode portion and a first horizontal electrode portion connected in series, wherein an included angle is provided between the first vertical electrode portion and the first horizontal electrode portion, and an end of the first vertical electrode portion away from the first horizontal electrode portion is electrically connected to the first main electrode;
in a case that a number of the sub-electrodes included in one branch electrode is k, the sub-electrodes are sequentially connected in the second direction, and k is satisfied with: k≥2, wherein k is positive integer; and
in the case that the number of the sub-electrodes included in one branch electrode is k, the first vertical electrode portion of an e-th sub-electrode and the first vertical electrode portion of an (e+1)-th sub-electrode are connected in series, and e and k are satisfied with: e≥1, k≥e+1, wherein e is positive integer.

5. The display panel of claim 4, wherein the first vertical electrode portion extends in the second direction and the first horizontal electrode portion extends in the first direction.

6. The display panel of claim 4, wherein in each of the quadrant regions, a number of the branch electrodes connected to the first main electrode is f, the first main electrode is equally divided by the branch electrodes into first segments of f, and a length of each of the first segments is a, wherein the first main electrode has equal points of f, and each of the branch electrodes is electrically connected to the first main electrode at a corresponding one of the equal points, wherein a length of the first horizontal electrode portion is less than a, and a and f are respectively satisfied with: f≥1, a>0, wherein f is positive integer;
in each of the quadrant regions, a number of the branch electrodes connected to the second main electrode is f, the second main electrode is equally divided by the branch electrodes into second segments of f, and a length of each of the second segments is b, and wherein a length of the first vertical electrode portion of the sub-electrode connected to the first main electrode is less than b, and b is satisfied with: b>0.

7. The display panel of claim 4, wherein in each of the quadrant regions, in a case that a number of the branch electrodes connected to the first main electrode is f, a number of the sub-electrodes of an n-th branch electrode is less than a number of the sub-electrodes of an m-th branch electrode, wherein the n-th and the m-th are defined in a direction from an end of the first main electrode close to the second main electrode to another end of the first main electrode away from the second main electrode; and f, m and n are satisfied with: f≥m>n≥1; wherein f, m, and n are all positive integers;
and wherein the number of the sub-electrodes of the n-th branch electrode is p less than the number of the sub-electrodes of the m-th branch electrode; and m, n and p are satisfied with m=n+1, p≥1; wherein p is positive integer.

8. The display panel of claim 4, wherein in each of the quadrant regions, f of in a case that a number of the branch electrodes connected to the first main electrode is f, a number of the sub-electrodes of an n-th branch electrode is less than a number of the sub-electrodes of an m-th branch electrode, a number of the sub-electrodes of an s-th branch electrode is less than the number of the sub-electrodes of the m-th branch electrode; wherein n-th, m-th, and s-th are defined in a direction from an end of the first main electrode close to the second main electrode to another end of the first main electrode away from the second main electrode; and f, s, m, and n are satisfied with: f≥s>m>n≥1; wherein f, s, m, and n are positive integers;
wherein the number of the sub-electrodes of the n-th branch electrode is p less than a number of the sub-electrodes of an (n+1)-th branch electrode, and the number of the sub-electrodes of the s-th branch electrode is p less than a number of the sub-electrodes of an (s−1)-th branch electrode; wherein m, n, s and p are satisfied with: m≥n+1, m≤s−1, p≥1; wherein p is positive integer.

9. The display panel of claim 3, wherein a plurality of sub-pixels arranged in an array are provided on the driving substrate, each of the plurality of sub-pixel corresponds to one of the light-emitting units, a pixel gap is provided between adjacent sub-pixels, the touch control unit corresponds to the pixel gap, and the main electrode and the branch electrode surround the sub-pixel; wherein the sub-pixel comprises a green sub-pixel, and the green sub-pixel has an arrangement direction same as an extension direction of the main electrode portion and the branch electrode portion around the green sub-pixel.

10. The display panel of claim 3, wherein in any adjacent quadrant regions, the branch electrodes in one of the quadrant regions and the branch electrodes in another of the quadrant regions are axially symmetrical.

11. The display panel of claim 10, wherein in each of the quadrant regions, the branch electrodes connected on the first main electrode and the branch electrodes connected on the second main electrode are axially symmetrical.

12. The display panel of claim 3, wherein the driving substrate comprises a driving circuit, at least one first signal line, and a plurality of second signal lines, the least one first signal line and the plurality of second signal lines are respectively disposed in a same layer as a part of a metal layer of the driving circuit, the cathode pattern is electrically connected to the at least one first signal line, and the touch control units is electrically connected to a corresponding one of the plurality of second signal lines.

13. The display panel of claim 12, wherein the driving substrate further comprises:
a planarization layer disposed on the driving circuit, wherein the planarization layer comprises a first opening provided corresponding to the second signal line, and the first opening exposes a portion of the second signal line; and
a pixel definition layer disposed on the planarization layer, wherein the pixel definition layer comprises a second opening provided corresponding to the first opening, and the first opening and the second opening define an undercut structure;
wherein the first electrode layer is disposed on a side of the pixel definition layer away from the planarization layer, the first electrode layer is disconnected at the undercut structure to form the cathode pattern and the touch control unit, and the touch control unit extends into the first opening and the second opening to electrically connect with the second signal line.

14. The display panel of claim 13, wherein the cathode pattern and the touch control unit has a vertical gap defined between the first opening and the second opening.

15. The display panel of claim 12, wherein at least one first bridge point is provided in each touch control unit, the touch control unit is electrically connected to the second signal line through the first bridge point, and the first bridge point is disposed at an intersection of the first main electrode and the second main electrode; and
at least one second bridge point is provided on the cathode pattern, the cathode pattern is electrically connected to the first signal line through the second bridge point, and the second bridge points is disposed in a unit gap between two adjacent touch control units.

16. The display panel of claim 15, wherein the second bridge point comprises a first sub-bridge point disposed a unit gap defined by adjacent four touch control units, and any adjacent four touch control units shares one first sub-bridge point.

17. The display panel of claim 16, wherein the second bridge point further comprises a second sub-bridge point disposed between two adjacent first sub-bridge points, and the second sub-bridge point has an equal distance to the two adjacent first sub-bridge points.

18. The display panel of claim 15, wherein a plurality of third bridge points are further provided on each touch control unit, the plurality of third bridge points are disposed on the first main electrode and the second main electrode, and the first sub-bridge point has an equal distance to the plurality of third bridge points.

19. An electronic device, comprising the display panel of claim 1.

20. An electronic device, comprising the display panel of claim 2.
